(19) United States
(12) Patent Application Publication
(10) Pub. No.: US 2025/0374648 A1
(43) Pub. Date: Dec. 4, 2025

(54) SEMICONDUCTOR DEVICE, POWER CONVERSION APPARATUS, AND METHOD FOR MANUFACTURING THE SAME

(71) Applicants: KABUSHIKI KAISHA TOSHIBA, Tokyo (JP); Toshiba Electronic Devices & Storage Corporation, Tokyo (JP)

(72) Inventor: Fumiyoshi KAWASHIRO, Tokyo (JP)

(73) Assignees: KABUSHIKI KAISHA TOSHIBA, Tokyo (JP); Toshiba Electronic Devices & Storage Corporation, Tokyo (JP)

(21) Appl. No.: 19/243,853

(22) Filed: Jun. 20, 2025

Related U.S. Application Data
(63) Continuation of application No. PCT/JP2024/013821, filed on Apr. 3, 2024.

(30) Foreign Application Priority Data
Jul. 31, 2023 (JP) 2023-124770

(51) Int. Cl. H10D 80/20; H01L 21/48; H01L 23/495; H01L 23/498; H02M 3/158

(52) U.S. Cl. CPC H10D 80/251; H01L 21/4825; H01L 21/4828; H01L 21/4835; H01L 21/4839; H01L 21/4842; H01L 21/4871; H01L 23/4951; H01L 23/49531; H01L 23/49562; H01L 23/49568; H01L 23/49575; H01L 23/49861; H02M 3/158

(57) ABSTRACT

According to an embodiment, a semiconductor device includes a semiconductor chip having a first surface on which a source electrode and a gate electrode are provided and a second surface that is opposed to the first sur face and on which a drain electrode is provided, a source terminal having a fourth surface exposed from a third surface of a package and a fifth surface coupled to the source electrode and having a shape different from a sha pe of the fourth surface, a gate terminal having a sixth surface exposed from the third surface of the package and a seventh surface coupled to the gate electrode and having a shape different from a shape of the sixth surface, and a drain terminal coupled to the drain electrode and having an eighth surface exposed from the third surface of the package.

### CROSS-REFERENCE TO RELATED APPLICATION

This application is a Continuation Application of PCT Application No. PCT/JP2024/013821, filed Apr. 3, 2024, and based upon and claiming the benefit of priority from Japanese Patent Application No. 2023-124770, filed Jul. 31, 2023, the entire contents of all of which are incorporated herein by reference.

### FIELD

Embodiments of the present invention relate to a semiconductor device, a power conversion apparatus, and a method for manufacturing the same.

### BACKGROUND

As a switching element used in a power conversion apparatus (for example, a DC-DC converter), a semiconductor device such as a power MOSFET surface-mounted on a printed circuit board is known.

### BRIEF DESCRIPTION OF THE DRAWINGS

FIG. 1 is a plan view of a package front surface of a semiconductor device according to a first embodiment.

FIG. 2 is a plan view of a package back surface of the semiconductor device according to the first embodiment.

FIG. 3 is a cross-sectional view taken along line A1-A2 in FIGS. 1 and 2.

FIG. 4 is a cross-sectional view taken along line B1-B2 in FIGS. 1 and 2.

FIG. 5 is a plan view of a first surface of a semiconductor chip included in the semiconductor device according to the first embodiment.

FIG. 6 is a plan view taken along line C1-C2 in FIGS. 3 and 4.

FIG. 7 is a plan view taken along line D1-D2 in FIGS. 3 and 4.

FIG. 8 illustrates a flow of an assembly process of the semiconductor device according to the first embodiment.

FIG. 9 is a plan view of a package front surface of a semiconductor device according to a second embodiment.

FIG. 10 is a plan view of a package back surface of the semiconductor device according to the second embodiment.

FIG. 11 is a cross-sectional view taken along line A3-A4 in FIGS. 9 and 10.

FIG. 12 is a cross-sectional view taken along line B3-B4 in FIGS. 9 and 10.

FIG. 13 is a plan view taken along line C3-C4 in FIGS. 11 and 12.

FIG. 14 is a plan view taken along line D3-D4 in FIGS. 11 and 12.

FIG. 15 illustrates a flow of an assembly process of the semiconductor device according to the second embodiment.

FIG. 16 is a plan view of a package front surface of a semiconductor device according to a third embodiment.

FIG. 17 is a cross-sectional view taken along line A5-A6 in FIG. 16.

FIG. 18 is a cross-sectional view taken along line B5-B6 in FIG. 16.

FIG. 19 illustrates a flow of an assembly process of the semiconductor device according to the third embodiment.

FIG. 20 is a plan view of a package front surface of a semiconductor device according to a fourth embodiment.

FIG. 21 is a cross-sectional view taken along line A7-A8 in FIG. 20.

FIG. 22 is a cross-sectional view taken along line B7-B8 in FIG. 20.

FIG. 23 illustrates a flow of an assembly process of the semiconductor device according to the fourth embodiment.

FIG. 24 is a circuit diagram of a power conversion apparatus according to a fifth embodiment.

FIG. 25 is a plan view of the power conversion apparatus according to the fifth embodiment.

FIG. 26 is a cross-sectional view taken along line X1-X2 in FIG. 25.

FIG. 27 is a plan view of a power conversion apparatus according to a sixth embodiment.

FIG. 28 is a cross-sectional view taken along line X3-X4 in FIG. 27.

FIG. 29 is a plan view of a power conversion apparatus according to a seventh embodiment.

FIG. 30 is a cross-sectional view taken along line X5-X6 in FIG. 29.

### DETAILED DESCRIPTION

In general, according to one embodiment, a semiconductor device includes a semiconductor chip having a first surface on which a source electrode and a gate electrode are provided and a second surface that is opposed to the first surface and on which a drain electrode is provided, a source terminal having a fourth surface exposed from a third surface of a package and a fifth surface coupled to the source electrode and having a shape different from a shape of the fourth surface, a gate terminal having a sixth surface exposed from the third surface of the package and a seventh surface coupled to the gate electrode and having a shape different from a shape of the sixth surface, and a drain terminal coupled to the drain electrode and having an eighth surface exposed from the third surface of the package.

Hereinafter, embodiments will be described with reference to the drawings. The following embodiments illustrate an apparatus and a method for embodying the technical idea of the embodiments, and do not limit materials, shapes, structures, positions, and the like of the constituent parts to those described below. In the drawings referred to below, in the present specification, constituent elements such as an insulating layer, a coating film, wiring, and contact are appropriately omitted in order to make the drawings easy to see.

### 1. First Embodiment

First, a first embodiment will be described. In the first embodiment, for example, a semiconductor device 1 including a metal oxide semiconductor field effect transistor (MOSFET) functioning as a switching element will be described. The MOSFET is used for a power conversion apparatus such as a DC-DC converter or an inverter. Note that a substrate on which the MOSFET is provided may be a Si substrate or may be a Sic substrate. The semiconductor device 1 may include an insulated gate bipolar transistor (IGBT) provided on a Si substrate instead of the MOSFET.

### 1.1 Configuration of Semiconductor Device

### 1.1.1 Planar Configuration of Semiconductor Device

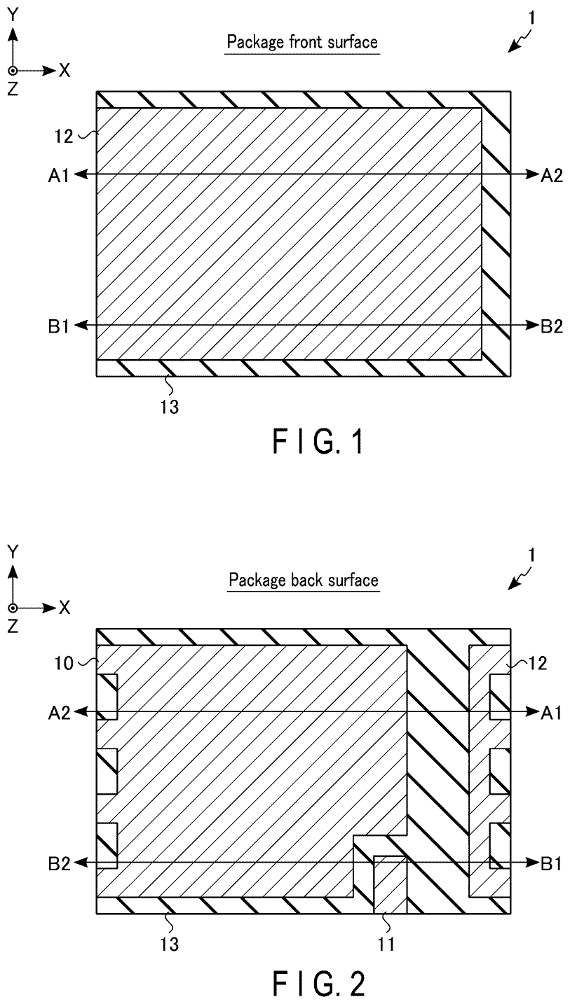

First, an example of a planar configuration of the semiconductor device 1 will be described. FIG. 1 is a plan view of a package front surface of the semiconductor device 1. FIG. 2 is a plan view of a back surface of the package of the semiconductor device 1. In the following description, for example, a mounting surface that is joined to a printed circuit board when the semiconductor device 1 is surface-mounted on the printed circuit board is referred to as a “package back surface”. A surface of the semiconductor device 1 that is opposed to the package back surface is referred to as a “package front surface”. In the example of FIGS. 1 and 2, a plane along the package front surface and the package back surface is referred to as an XY plane. A direction connecting a drain terminal and a source terminal on the package back surface is referred to as an X direction, and a direction intersecting the X direction is referred to as a Y direction. A direction intersecting the XY plane is referred to as a Z direction. A surface of the semiconductor device 1 facing the X direction or the Y direction is referred to as a “package side surface”.

As illustrated in FIGS. 1 and 2, the semiconductor device 1 includes a source terminal 10, a gate terminal 11, a drain terminal 12, and a molding resin 13. An etched lead frame (hereinafter also referred to as an “etching frame”) is used for the source terminal 10, the gate terminal 11, and the drain terminal 12. The source terminal 10, the gate terminal 11, and the drain terminal 12 are made of a conductive material, and contain, for example, copper. The conductive material may contain a high-melting-point material. A surface (hereinafter referred to as an “exposed surface”) of each terminal exposed from the molding resin 13 may be covered with a material such as tin (Sn) or solder or may be covered with no material. The semiconductor device 1 of the present embodiment can be applied to surface mounting and vertical mounting. For example, in the case of surface mounting applications, the exposed surface of each terminal is covered with a material such as tin or solder. For example, in the case of vertical mounting applications, the exposed surface of each terminal is not covered with a material such as tin or solder. For example, in a case where the semiconductor device 1 is embedded in a printed circuit board by vertical mounting, a Cu-plated wiring is formed. Therefore, it is preferable that the exposed surface of each terminal is not covered with a material such as tin or solder. Note that although FIGS. 1 and 2 illustrate a structure in which each terminal (lead terminal) does not protrude from the molding resin 13 (that is, the package) as in, for example, a dual flatpack non-leaded (DFN), the present invention is not limited to this. Each terminal may protrude from the molding resin 13.

The exposed surfaces of the source terminal 10 and the gate terminal 11 are provided on the package back surface. The exposed surfaces of the source terminal 10 and the gate terminal 11 are electrically coupled to the printed circuit board with solder or the like interposed therebetween. The exposed surfaces of the source terminal 10 and the gate terminal 11 may have any shapes. In the example of FIG. 2, four protrusions are provided at one end of the source terminal 10 facing the X direction. For example, the four protrusions extend to an end of the molding resin 13 (package) facing the X direction. The four protrusions are exposed on a package side surface facing the X direction on the side on which the four protrusions extend. In the assembly process of the semiconductor device 1, when a plurality of semiconductor devices 1 are diced into individual pieces, a cut surface of the etching frame forming the source terminal 10 may be exposed from the package side surface.

The exposed surface of the gate terminal 11 has, for example, a rectangular shape. For example, one end of the gate terminal 11 facing the Y direction extends to an end of the molding resin 13 facing the Y direction. The gate terminal 11 is exposed on a package side surface facing the Y direction.

The exposed surface of the drain terminal 12 is provided on the package front surface and the package back surface. For example, the drain terminal 12 can be electrically coupled to the printed circuit board on the package front surface or the package back surface. The exposed surface of the drain terminal 12 may have any shape. In the example of FIG. 1, the exposed surface of the drain terminal 12 on the package front surface has a rectangular shape. For example, one end of the drain terminal 12 facing the X direction extends to an end of the molding resin 13 facing the X direction. In the example of FIG. 2, the exposed surface of the drain terminal 12 on the package back surface faces the source terminal 10 in the X direction. Four protrusions are provided at one end of the drain terminal 12 facing the X direction. For example, the four protrusions extend to an end of the molding resin 13 facing the X direction. The drain terminal 12 is exposed on a package side surface facing the X direction.

The molding resin 13 seals the semiconductor device 1. The molding resin 13 stably holds an insulating state and arrangement of a semiconductor chip (not illustrated), the source terminal 10, the gate terminal 11, and the drain terminal 12 in the semiconductor device 1. As the molding resin 13, for example, an epoxy resin is used. The molding resin 13 may contain a filler such as silicon oxide.

### 1.1.2 Cross-Sectional Configuration of Semiconductor Device

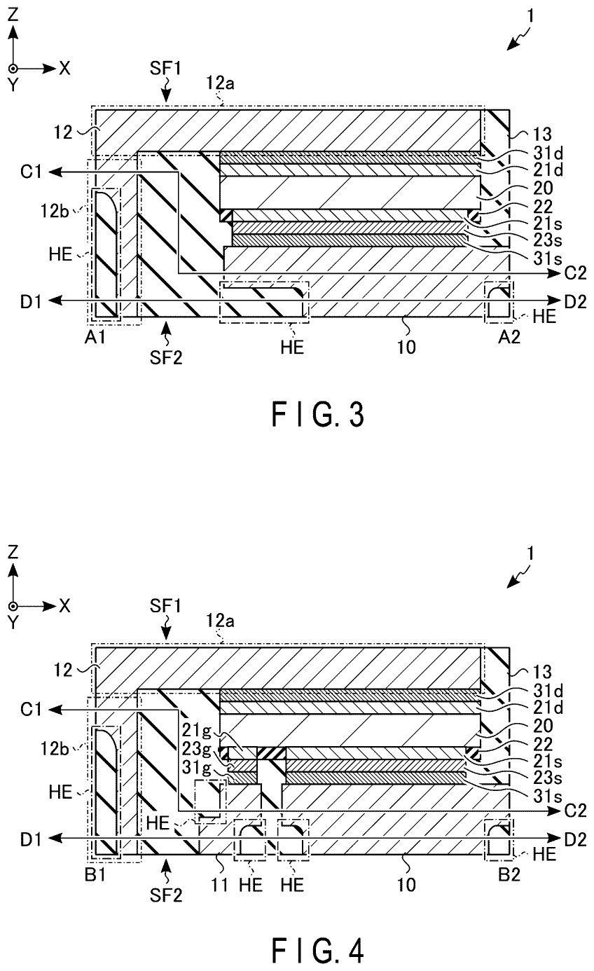

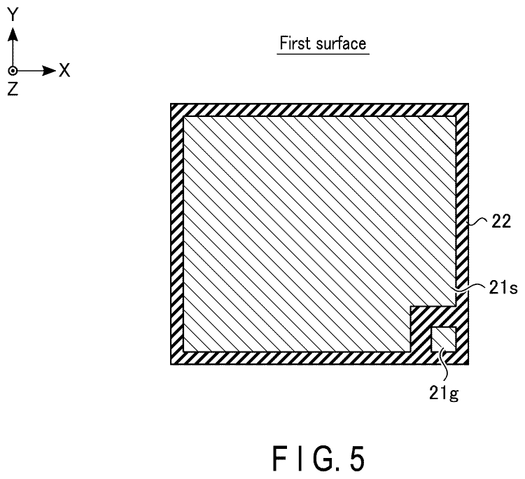

Next, an example of a cross-sectional configuration of the semiconductor device 1 will be described. FIG. 3 is a cross-sectional view taken along line A1-A2 in FIGS. 1 and 2. FIG. 4 is a cross-sectional view taken along line B1-B2 in FIGS. 1 and 2. FIG. 5 is a plan view of a first surface of a semiconductor chip 20. In the example of FIG. 5, conductive layers 23s and 23g, which will be described later, are omitted.

As illustrated in FIGS. 3 and 4, the semiconductor device 1 further includes the semiconductor chip 20 and mount materials 31s, 31g, and 31g.

The semiconductor chip 20 is, for example, a MOSFET. The semiconductor chip 20 is disposed between the source terminal 10 and gate terminal 11, and the drain terminal 12. In the following description, a surface of the semiconductor chip 20 that intersects with the Z direction and faces the source terminal 10 and the gate terminal 11 is referred to as a “first surface”. A surface of the semiconductor chip 20 that is opposed to the first surface and faces the drain terminal 12 is referred to as a “second surface”.

The semiconductor chip 20 includes a source electrode 21s, a gate electrode 21g, a drain electrode 21d, a passivation film 22, and conductive layers 23s and 23g.

The source electrode 21s and the gate electrode 21g are provided on the first surface of the semiconductor chip 20. As illustrated in FIG. 5, the passivation film 22 is provided so as to surround the source electrode 21s and the gate electrode 21g. The conductive layer 23s and the conductive layer 23g are provided on the source electrode 21s and the gate electrode 21g, respectively. The configuration in which the second surface of the semiconductor chip 20 on which the source electrode 21s and the like faces a package back surface SF2 can also be referred to as “source-down package”.

As illustrated in FIGS. 3 and 4, the drain electrode 21d is provided on the second surface of the semiconductor chip 20.

The source electrode 21s is coupled to a source of the MOSFET. The gate electrode 21g is coupled to a gate of the MOSFET. The drain electrode 21d is coupled to a drain of the MOSFET. The source electrode 21s, the gate electrode 21g, and the drain electrode 21d are made of a conductive material. The source electrode 21s and the gate electrode 21g contain, for example, aluminum. The drain electrode 21d contains, for example, a laminated film of titanium/nickel/gold, an alloy of gold and silver, or silver.

The passivation film 22 physically and electrically separates the source electrode 21s and the gate electrode 21g. For the passivation film 22, for example, a resin material such as polyimide is used.

The conductive layers 23s and 23g are formed by, for example, a dry process such as sputtering or vapor deposition or a wet process such as electrolytic plating or electroless plating. The conductive layers 23s and 23g contain, for example, at least one of copper, nickel, silver, gold, or palladium.

The mount material 31s joins the conductive layer 23s and the source terminal 10. The mount material 31g joins the conductive layer 23g and the gate terminal 11. The mount material 31d joins the drain electrode 21d and the drain terminal 12. Hereinafter, surfaces of the source terminal 10, the gate terminal 11, and the drain terminal 12 that are joined to the semiconductor chip 20 are referred to as “chip joint surfaces”. The mount materials 31s, 31g, and 31d are made of a conductive material. For example, solder is used for the mount materials 31s, 31g, and 31d. Instead of the solder, a hardly soluble sintered material (for example, any one of copper, silver, lead, a tin copper compound, a tin silver compound, and a tin nickel compound) may be used. In that case, a pressure sintered material having excellent pressure resistance may be used.

The source terminal 10 and the gate terminal 11 are formed of the same etching frame. Therefore, the source terminal 10 and the gate terminal 11 have substantially the same thickness (height in the Z direction).

The source terminal 10 has a half-etched region HE half-etched in the Z direction from an exposed surface of the package back surface SF2. In other words, the source terminal 10 has, on the chip joint surface side, a protruding portion protruding in the X direction and/or the Y direction from the exposed surface. A part of an end portion of the chip joint surface of the source terminal 10 protrudes from the exposed surface. Note that the half-etched region HE may have any height in the Z direction. In the example of FIGS. 3 and 4, at both ends in the X direction, the half-etched region HE is provided from the exposed surface of the package back surface SF2 (lower side in the drawing) toward the chip joint surface joined to the semiconductor chip 20.

Therefore, the area and shape of the exposed surface of the source terminal 10 are different from the area and shape of the chip joint surface. In the example of FIGS. 3 and 4, the protruding portion of the source terminal 10 on the chip joint surface side is exposed from the package side surface in the X direction. By expanding the chip joint surface to the package side surface, a chip size of the semiconductor chip 20 mountable on the semiconductor device 1 can be increased.

As illustrated in FIG. 4, the gate terminal 11 has a half-etched region HE half-etched in the Z direction from the exposed surface and a half-etched region HE half-etched in the Z direction from the chip joint surface. That is, the gate terminal 11 has a shape half-etched from both the exposed surface and the chip joint surface. In other words, the gate terminal 11 has, on the chip joint surface side, a protrusion protruding in the X direction and/or the Y direction from the exposed surface, and has, on the exposed surface side, a protrusion protruding in the X direction and/or the Y direction from the chip joint surface. A height in the Z direction of the half-etched region HE half-etched in the Z direction from the exposed surface of the gate terminal 11 is substantially the same as the height in the Z direction of the half-etched region HE of the source terminal 10. The area and shape of the exposed surface of the gate terminal 11 are different from the area and shape of the chip joint surface. As a result, the exposed surface of the gate terminal 11 can be freely positioned on the package back surface SF2 regardless of the position of the gate electrode 21g of the semiconductor chip 20.

For example, the etching frame constituting the drain terminal 12 is formed by etching a lead frame thicker than the etching frame constituting the source terminal 10 and the gate terminal 11. For example, the etching frame used for the drain terminal 12 has the same thickness as the package. The etching frame is etched from the package back surface side to form a region where the semiconductor chip 20, the source terminal 10, and the gate terminal 11 are mounted.

The drain terminal 12 includes a first portion 12a and a second portion 12b. The first portion 12a is a plate-shaped portion extending on the XY plane. A surface of the first portion 12a facing the package front surface side is exposed from a package front surface SF1. A surface of the first portion 12a facing the package back surface side is a chip joint surface to which the drain electrode 21d is joined with the mount material 31d interposed therebetween. One end of the second portion 12b is coupled to an end of the first portion 12a in the X direction. The second portion 12b extends in the Z direction. Another end of the second portion 12b is exposed on the package back surface SF2.

The second portion 12b of the drain terminal 12 has, on the package side surface facing the X direction, a half-etched region HE half-etched in the Z direction from the exposed surface of the package back surface SF2. In other words, the drain terminal 12 has a protruding portion protruding in the X direction from the exposed surface. A height in the Z direction of the half-etched region HE of the drain terminal 12 may be different from the heights in the Z direction of the half-etched regions HE of the source terminal 10 and the gate terminal 11. For example, a length in the Z direction of the half-etched region HE of the drain terminal 12 may be longer than lengths in the Z direction of the half-etched regions HE of the source terminal 10 and the gate terminal 11. In the X direction, a non-half-etched end portion (protruding portion) of the drain terminal 12 is exposed from the package side surface.

Although the half-etched regions HE of the source terminal 10 and the drain terminal 12 are sealed with the molding resin 13 on the package side surface in the example of FIGS. 3 and 4, the molding resin 13 in this region may be omitted. That is, the half-etched region HE of each terminal may be exposed on the package side surface. The same applies to an end portion of the gate terminal 11 in the Y direction (not illustrated). Therefore, wettable flank is applicable to the semiconductor device 1. For example, when the semiconductor device 1 is surface-mounted on the printed circuit board, solder flows around to the half-etched region HE exposed on the package side surface, and it can be thus confirmed that soldering operation has been normally performed.

As with the gate terminal 11, the source terminal 10 may have a half-etched region HE half-etched in the Z direction from the chip joint surface. To improve mounting accuracy of the semiconductor chip 20, a slit (half-etched region HE) corresponding to the chip size may be formed on the chip joint surface of the source terminal 10.

### 1.1.3 Planar Configuration of Each Terminal

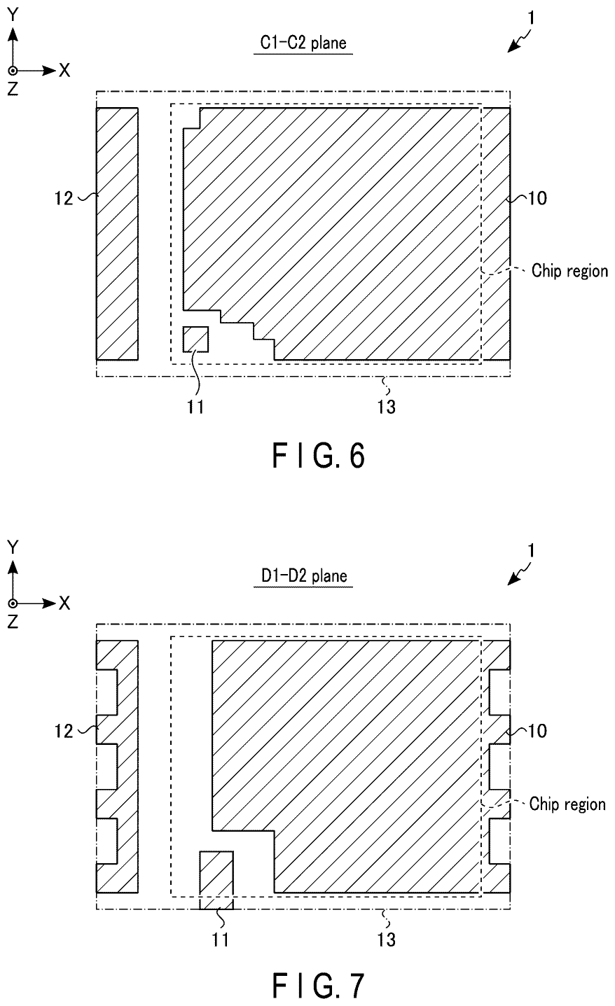

Next, an example of a planar configuration of each terminal will be described. FIG. 6 is a plan view taken along line C1-C2 in FIGS. 3 and 4. FIG. 7 is a plan view taken along line D1-D2 in FIGS. 3 and 4. FIG. 6 illustrates the chip joint surfaces of the source terminal 10 and the gate terminal 11 and a shape of a portion that does not include the half-etched region HE of the drain terminal 12. FIG. 7 illustrates shapes of the exposed surfaces of the source terminal 10, the gate terminal 11, and the drain terminal 12 on the package back surface SF2. FIGS. 6 and 7 are plan views viewed from the package front surface side. In FIGS. 6 and 7, a chip region where the semiconductor chip 20 is disposed is indicated by a broken line. The following description will be given focusing on the source terminal 10 and the gate terminal 11.

As illustrated in FIGS. 6 and 7, the shapes of the chip joint surfaces of the source terminal 10 and the gate terminal 11 are different from the shapes of the exposed surfaces on the package back surface SF2. For example, the areas of the chip joint surfaces of the source terminal 10 and the gate terminal 11 are larger than the areas of the exposed surfaces on the package back surface SF2. For example, a position of the joint surface of the gate terminal 11 on the XY plane is different from a position of the exposed surface of the gate terminal 11 on the XY plane.

The shapes of chip joint surfaces of the source terminal 10 and the gate terminal 11 are designed based on the semiconductor chip 20 mounted on the semiconductor device 1. For example, an end portion of the chip joint surface of the source terminal 10 extends to the package side surface. This improves an available degree of freedom of layout of the source electrode 21s and the gate electrode 21g of the semiconductor chip 20. Furthermore, the chip size of the semiconductor chip 20 that can be mounted can be made larger than the layout of the exposed surfaces of the source terminal 10 and the gate terminal 11. This improves mounting capability of the semiconductor chip 20.

The shapes of the exposed surfaces of the source terminal 10, the gate terminal 11, and the drain terminal 12 on the package back surface SF2 can be, for example, shapes having compatibility with layout of DEN or the like of a ready-made product. This improves versatility (compatibility) of the semiconductor device 1.

### 1.2 Method for Manufacturing Semiconductor Device

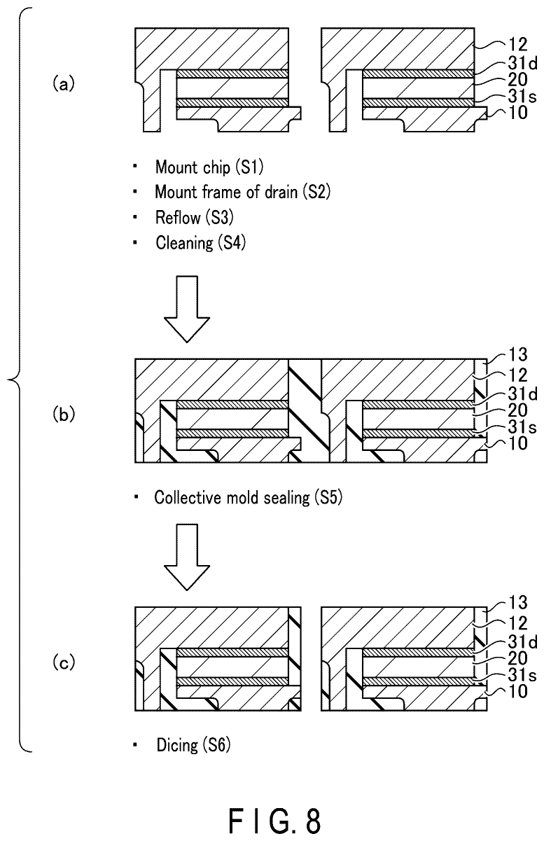

Next, an example of a method for manufacturing the semiconductor device 1 will be described. FIG. 8 is a diagram illustrating a flow of an assembly process. Note that the example of FIG. 8 illustrates a cross section of the semiconductor device 1 taken along line A1-A2 in FIGS. 1 and 2, and the gate terminal 11 is omitted in order to simplify the description. Furthermore, in the example of FIG. 8, the source electrode 21s, the gate electrode 21g, the drain electrode 21d, the passivation film 22, and the conductive layers 23s and 23g are omitted.

As illustrated in FIG. 8(a), first, a first etching frame provided with a plurality of source terminals 10 and a plurality of gate terminals 11 corresponding to a plurality of semiconductor devices 1 is prepared. Each semiconductor chip 20 is mounted so that the source terminal 10 and the source electrode 21s are coupled with the mount material 31s interposed therebetween and the gate terminal 11 and the gate electrode 21g are coupled with the mount material 31g interposed therebetween (S1). Next, a second etching frame provided with the drain terminal 12 is mounted on the drain electrode 21d of the semiconductor chip 20 with the mount material 31d interposed therebetween (S2). The second etching frame is thicker than the first etching frame. In this state, reflow (S3) and cleaning (S4) are performed. In a case where residue of the mount materials 31 does not cause defects such as insulation failure and delamination, the cleaning may be omitted. Note that the mount material 31d, the semiconductor chip 20, the mount materials 31s and 31g, and the first etching frame provided with the source terminal 10 and the gate terminal 11 may be sequentially mounted on the second etching frame provided with the drain terminal 12.

As illustrated in FIG. 8(b), the plurality of semiconductor devices 1 sharing the first etching frame and the second etching frame are collectively sealed with the molding resin 13 (S5). That is, a molding process is performed. In the molding, the etching frame may be, for example, covered with a release film so that the molding resin does not flow around to a half-etching portion.

As illustrated in FIG. 8(c), the molding resin 13, the first etching frame, and the second etching frame are cut by blade dicing (S6). The semiconductor devices 1 are thus cut into individual pieces. Cut surfaces of the first etching frame and the second etching frame cut by the dicing may be exposed on a package side surface.

With the configuration according to the present embodiment, a half-etched etching frame can be applied to the source terminal 10, the gate terminal 11, and the drain terminal 12 of the semiconductor device 1. As a result, the exposed surfaces of the source terminal 10 and the gate terminal 11 can have shapes different from the chip joint surfaces. Layout of the chip joint surfaces is not limited to layout of the exposed surfaces. Accordingly, a degree of freedom of layout of the semiconductor chip 20 can be improved. Furthermore, a mountable chip size can be increased. It is therefore possible to improve mounting capability of the semiconductor chip 20.

Furthermore, the exposed surfaces of the source terminal 10 and the gate terminal 11 can be made the same as layout of a ready-made product. Therefore, compatibility and versatility of the semiconductor device 1 can be improved.

Furthermore, with the configuration according to the present embodiment, the drain terminal 12 can be exposed on both of the package front surface SF1 and the package back surface SF2. This can improve heat dissipation of the semiconductor device 1.

The drain terminal 12 can be electrically coupled to the printed circuit board from both the package front surface SF1 and the package back surface SF2. That is, the semiconductor device 1 has two mounting surfaces. Therefore, the semiconductor device 1 can be applied not only to surface mounting but also to vertical mounting such as embedding in a printed circuit board. That is, a degree of freedom in mounting the semiconductor device 1 can be improved.

### 2. Second Embodiment

Next, a second embodiment will be described. In the second embodiment, a configuration of a semiconductor device 1 different from that of the first embodiment will be described. Differences from the first embodiment will be mainly described below.

### 2.1 Configuration of Semiconductor Device

### 2.1.1 Planar Configuration of Semiconductor Device

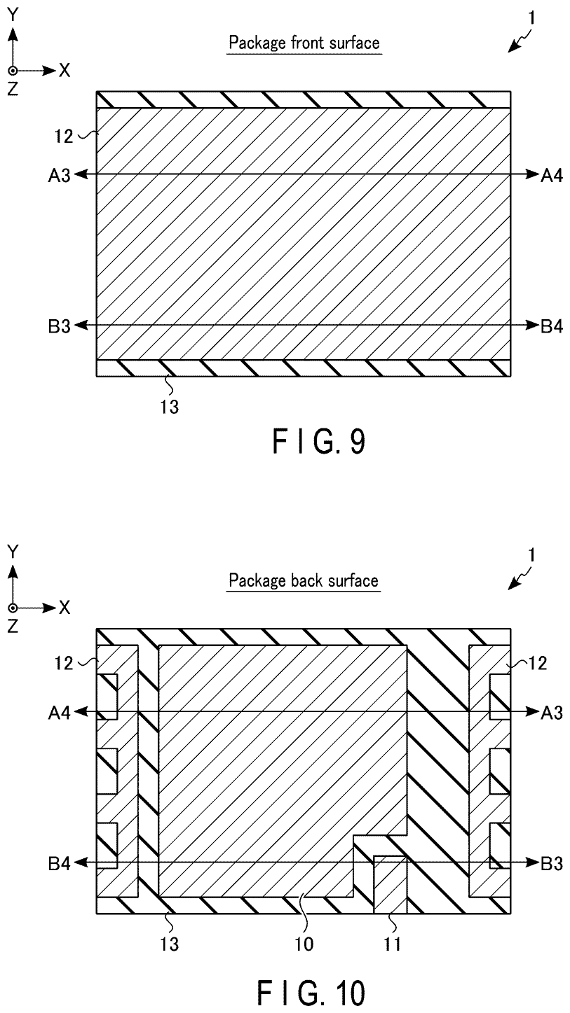

First, an example of a planar configuration of the semiconductor device 1 will be described. FIG. 9 is a plan view of a package front surface SF1 of the semiconductor device 1. FIG. 10 is a plan view of a package back surface SF2 of the semiconductor device 1.

As illustrated in FIGS. 9 and 10, in the present embodiment, an exposed surface of a drain terminal 12 is provided at both ends in the X direction on the package back surface SF2. In the example of FIG. 9, an exposed surface of the drain terminal 12 on the package front surface SF1 has a rectangular shape. For example, both ends of the drain terminal 12 facing the X direction extend to both ends of a molding resin 13 facing the X direction, respectively. In the example of FIG. 10, four protrusions are provided on each of two exposed surfaces of the drain terminal 12 provided at both ends in the X direction. For example, the four protrusions extend to an end of the molding resin 13 facing the X direction.

An exposed surface of a source terminal 10 is provided at a central portion of the package back surface SF2 and is not in contact with any end of the molding resin 13. Note that an end of the exposed surface of the source terminal 10 facing the Y direction may extend to an end of the molding resin 13 facing the Y direction.

An exposed surface of a gate terminal 11 is similar to that described in the first embodiment with reference to FIG. 2.

### 2.1.2 Cross-Sectional Configuration of Semiconductor Device

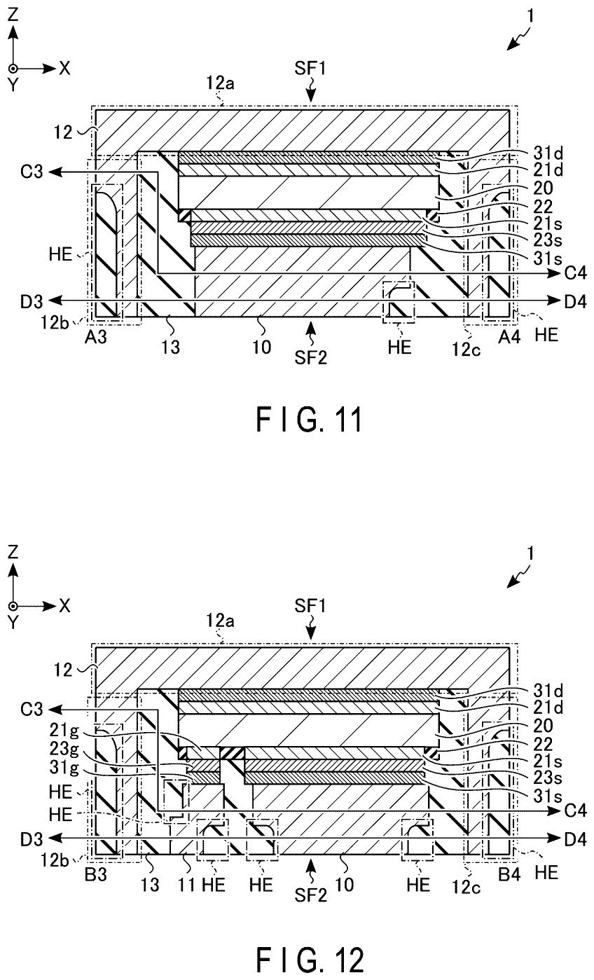

Next, an example of a cross-sectional configuration of the semiconductor device 1 will be described. FIG. 11 is a cross-sectional view taken along line A3-A4 in FIGS. 9 and 10. FIG. 12 is a cross-sectional view taken along line B3-B4 in FIGS. 9 and 10.

As illustrated in FIGS. 11 and 12, the source terminal 10 has a half-etched region HE half-etched from the exposed surface in the Z direction, as in the first embodiment. Although the half-etched region HE is provided at one end of the source terminal 10 facing the X direction in the example of FIG. 11, the half-etched region HE may be provided at both ends facing the X direction.

The gate terminal 11 is similar to that described in the first embodiment with reference to FIG. 4.

The drain terminal 12 includes a first portion 12a, a second portion 12b, and a third portion 12c. The first portion 12a is a plate-shaped portion extending on the XY plane. A surface of the first portion 12a facing the package front surface side is exposed from the package front surface SF1. A surface of the first portion 12a facing the package back surface side is a chip joint surface to which a drain electrode 21d is joined with a mount material 31d interposed therebetween. One end of the second portion 12b is coupled to one end of the first portion 12a in the X direction. The second portion 12b extends in the Z direction. Another end of the second portion 12b is exposed on the package back surface SF2. One end of the third portion 12c is coupled to the other end of the first portion 12a in the X direction. The third portion 12c extends in the Z direction. Another end of the third portion 12c is exposed on the package back surface SF2. The third portion 12c faces the second portion 12b across a semiconductor chip 20 in the X direction.

The second portion 12b and the third portion 12c of the drain terminal 12 have, at both ends facing the X direction, a half-etched region HE half-etched in the Z direction from the exposed surface on the package back surface SF2. In the X direction, two non-half-etched end portions of the drain terminal 12 are exposed from package side surfaces.

### 2.1.3 Planar Configuration of Each Terminal

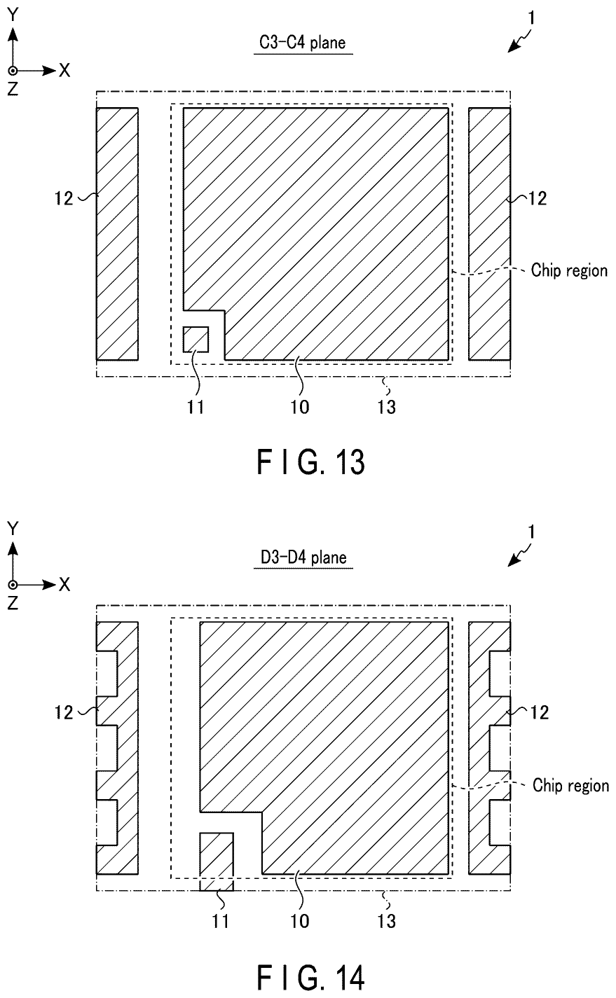

Next, an example of a planar configuration of each terminal will be described. FIG. 13 is a plan view taken along line C3-C4 in FIGS. 11 and 12. FIG. 14 is a plan view taken along line D3-D4 in FIGS. 11 and 12. FIG. 13 illustrates the chip joint surfaces of the source terminal 10 and the gate terminal 11 and a shape of a portion that does not include the half-etched region HE of the drain terminal 12. FIG. 14 illustrates shapes of the exposed surfaces of the source terminal 10, the gate terminal 11, and the drain terminal 12 on the package back surface SF2. FIGS. 13 and 14 are plan views viewed from the package front surface side. The following description will be given focusing on the source terminal 10 and the gate terminal 11.

As illustrated in FIGS. 13 and 14, the shapes of the chip joint surfaces of the source terminal 10 and the gate terminal 11 are different from the shapes of the exposed surfaces on the package back surface SF2. The shapes of the chip joint surfaces of the source terminal 10 and the gate terminal 11 do not correspond to the shapes of the exposed surfaces. The semiconductor chip 20 is disposed between the two drain terminals 12 provided at both ends in the X direction.

### 2.2 Method for Manufacturing Semiconductor Device

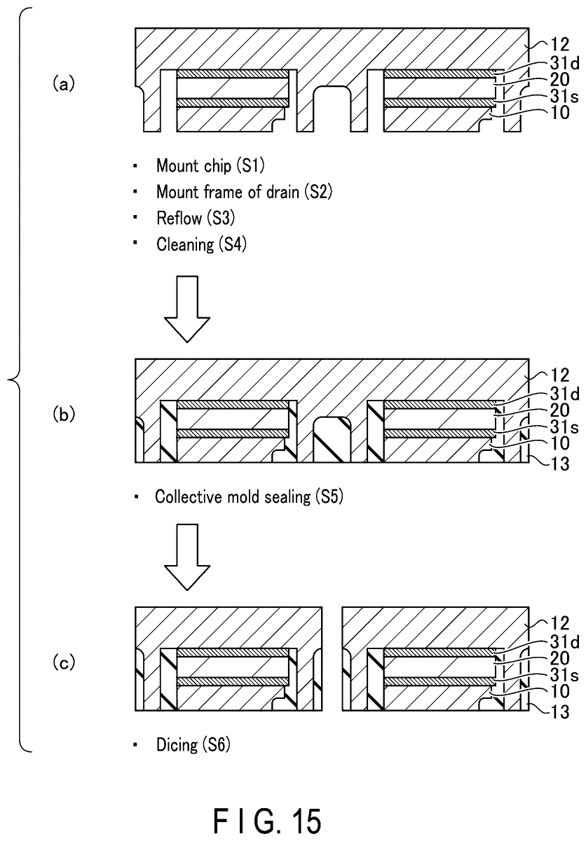

Next, an example of a method for manufacturing the semiconductor device 1 will be described. FIG. 15 is a diagram illustrating a flow of an assembly process. Note that the example of FIG. 15 illustrates a cross section of the semiconductor device 1 taken along line A3-A4 in FIGS. 9 and 10, and the gate terminal 11 is omitted in order to simplify the description. Furthermore, in the example of FIG. 15, a source electrode 21s, a gate electrode 21g, the drain electrode 21d, a passivation film 22, and conductive layers 23s and 23g are omitted.

As illustrated in FIG. 15(a), first, a first etching frame provided with a plurality of source terminals 10 and a plurality of gate terminals 11 corresponding to a plurality of semiconductor devices 1 is prepared, as in the description in the first embodiment given with reference to FIG. 8. Each semiconductor chip 20 is mounted so that the source terminal 10 and the source electrode 21s are coupled with the mount material 31s interposed therebetween and the gate terminal 11 and the gate electrode 21g are coupled with the mount material 31g interposed therebetween (S1). Next, a second etching frame provided with the drain terminal 12 is mounted on the drain electrode 21d of the semiconductor chip 20 with the mount material 31d interposed therebetween (S2). The second etching frame is thicker than the first etching frame. In this state, reflow (S3) and cleaning (S4) are performed. Note that the mount material 31d, the semiconductor chip 20, the mount materials 31s and 31g, and the first etching frame provided with the source terminal 10 and the gate terminal 11 may be sequentially mounted on the second etching frame provided with the drain terminal 12.

As illustrated in FIG. 15(b), the plurality of semiconductor devices 1 sharing the first etching frame and the second etching frame are collectively sealed with the molding resin 13 (S5). That is, a molding process is performed.

As illustrated in FIG. 15(c), the molding resin 13, the first etching frame, and the second etching frame are cut by blade dicing (S6). The semiconductor devices 1 are thus cut into individual pieces. Cut surfaces of the first etching frame and the second etching frame cut by the dicing may be exposed on a package side surface.

According to the configuration according to the present embodiment, similar effects to those of the first embodiment can be obtained.

Although the case where the exposed surface of the drain terminal 12 is provided at both ends in the X direction on the package back surface SF2 has been described in the second embodiment, the present invention is not limited to this. For example, the exposed surface of the drain terminal 12 may be provided at four end portions or four corners of the package back surface SF2.

### 3. Third Embodiment

Next, a third embodiment will be described. In the third embodiment, a configuration of a semiconductor device 1 different from that of the first and second embodiments will be described. Differences from the first and second embodiments will be mainly described below.

### 3.1 Configuration of Semiconductor Device

### 3.1.1 Planar Configuration of Semiconductor Device

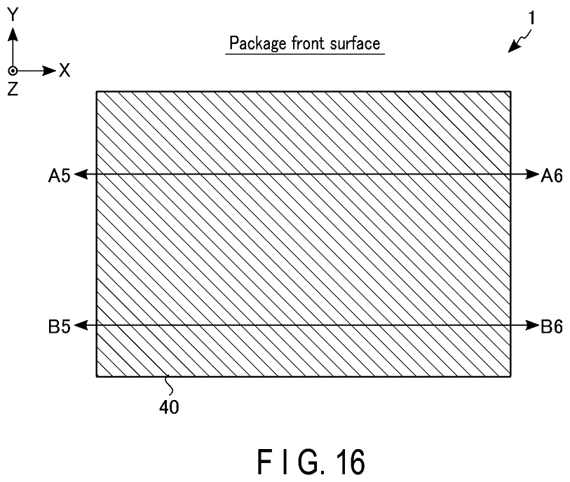

First, an example of a planar configuration of the semiconductor device 1 will be described. FIG. 16 is a plan view of a package front surface SF1 of the semiconductor device 1.

As illustrated in FIG. 16, the semiconductor device 1 of the present embodiment further includes a heat sink 40 in addition to the configuration described in the first embodiment. For the heat sink 40, a conductive material having good thermal conductivity is used. For example, copper is used for the heat sink 40. For example, the heat sink 40 is provided on an entire surface of the package front surface SF1. Configurations of exposed surfaces of a source terminal 10, a gate terminal 11, and a drain terminal 12 on a package back surface SF2 are similar to those of the first embodiment described with reference to FIG. 2.

### 3.1.2 Cross-Sectional Configuration of Semiconductor Device

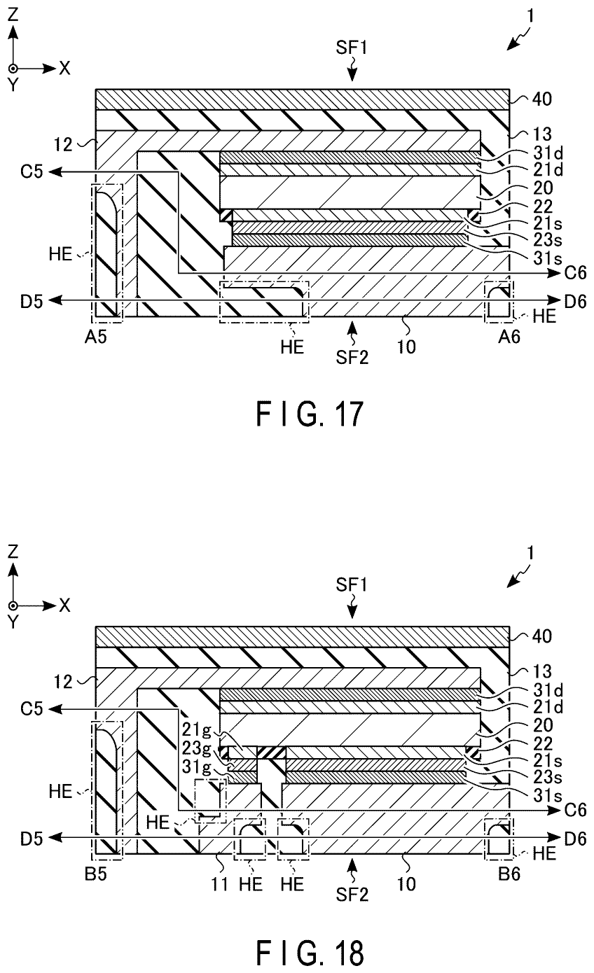

Next, an example of a cross-sectional configuration of the semiconductor device 1 will be described. FIG. 17 is a cross-sectional view taken along line A5-A6 in FIG. 16. FIG. 18 is a cross-sectional view taken along line B5-B6 in FIG. 16.

As illustrated in FIGS. 17 and 18, cross-sectional configurations of the source terminal 10, the gate terminal 11, and the drain terminal 12 are similar to those in the first embodiment described with reference to FIGS. 3 and 4.

The heat sink 40 is provided on the package front surface SF1 (the upper side in FIGS. 17 and 18). A molding resin 13 is provided between the heat sink 40 and a surface of the drain terminal 12 facing the package front surface SF1. The heat sink 40 is not in contact with the drain terminal 12 since the molding resin 13 is interposed therebetween. That is, the heat sink 40 is insulated from the source terminal 10, the gate terminal 11, and the drain terminal 12.

### 3.2 Method for Manufacturing Semiconductor Device

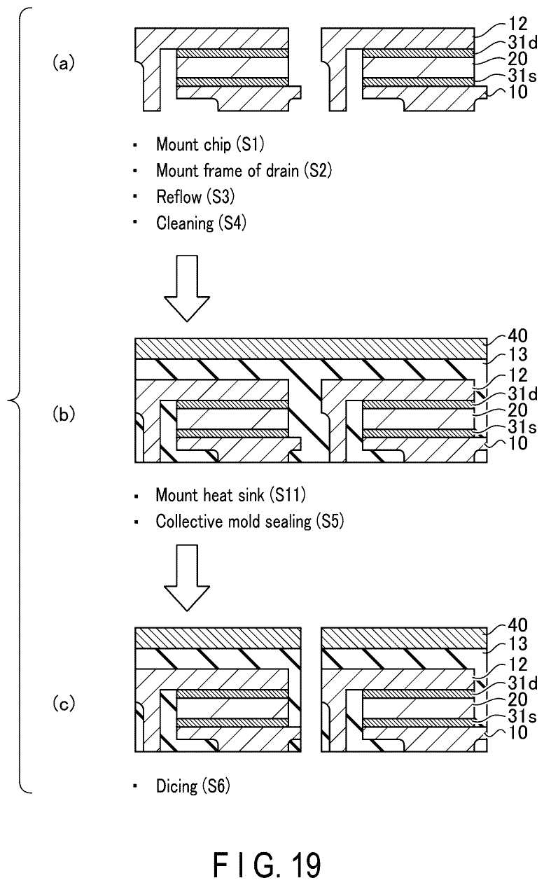

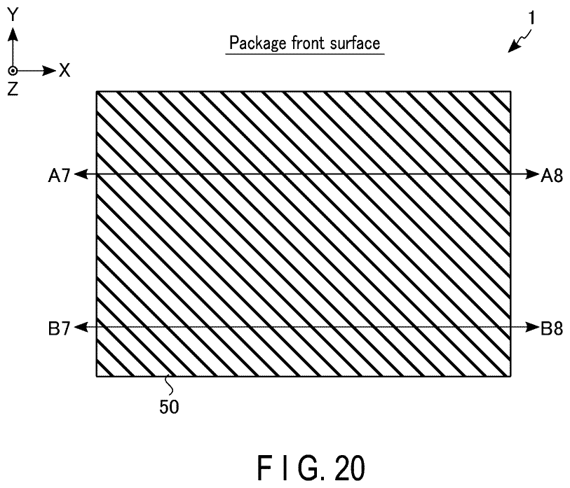

Next, an example of a method for manufacturing the semiconductor device 1 will be described. FIG. 19 is a diagram illustrating a flow of an assembly process. Note that the example of FIG. 19 illustrates a cross section of the semiconductor device 1 taken along line A5-A6 in FIG. 16, and the gate terminal 11 is omitted in order to simplify the description. Furthermore, in the example of FIG. 19, a source electrode 21s, a gate electrode 21g, a drain electrode 21d, a passivation film 22, and conductive layers 23s and 23g are omitted.

As illustrated in FIG. 19(a), first, a first etching frame provided with a plurality of source terminals 10 and a plurality of gate terminals 11 corresponding to a plurality of semiconductor devices 1 is prepared, as in the description in the first embodiment given with reference to FIG. 8. Each semiconductor chip 20 is mounted so that the source terminal 10 and the source electrode 21s are coupled with the mount material 31s interposed therebetween and the gate terminal 11 and the gate electrode 21g are coupled with the mount material 31g interposed therebetween (S1). Next, a second etching frame provided with the drain terminal 12 is mounted on the drain electrode 21d of the semiconductor chip 20 with a mount material 31d interposed therebetween (S2). The second etching frame is thicker than the first etching frame. In this state, reflow (S3) and cleaning (S4) are performed. Note that the mount material 31d, the semiconductor chip 20, the mount materials 31s and 31g, and the first etching frame provided with the source terminal 10 and the gate terminal 11 may be sequentially mounted on the second etching frame provided with the drain terminal 12.

As illustrated in FIG. 19(b), after the heat sink 40 is mounted (S11), the plurality of semiconductor devices 1 sharing the first etching frame and the second etching frame are collectively sealed with the molding resin 13 (S5). That is, a molding process is performed.

As illustrated in FIG. 19(c), the heat sink 40, the molding resin 13, the first etching frame, and the second etching frame are cut by blade dicing (S6). The semiconductor devices 1 are thus cut into individual pieces. Cut surfaces of the first etching frame, the second etching frame, and the heat sink 40 cut by the dicing may be exposed on a package side surface.

With the configuration according to the present embodiment, mounting capability of the semiconductor chip 20 can be improved as in the first embodiment.

Furthermore, with the configuration according to the present embodiment, in a case where the drain terminal 12 is not electrically connected to a wire on the package front surface SF1, the heat sink 40 can be provided on the package front surface SF1. This can improve heat dissipation of the semiconductor device 1.

The structure of the third embodiment can also be applied to the second embodiment.

### 4. Fourth Embodiment

Next, a fourth embodiment will be described. In the fourth embodiment, a configuration of a semiconductor device 1 different from that of the first to third embodiments will be described. Differences from the first and second embodiments will be mainly described below.

### 4.1 Configuration of Semiconductor Device

### 4.1.1 Planar Configuration of Semiconductor Device

First, an example of a planar configuration of the semiconductor device 1 will be described. FIG. 20 is a plan view of a package front surface SF1 of the semiconductor device 1.

As illustrated in FIG. 20, the semiconductor device 1 of the present embodiment further includes an insulating resin 50 in addition to the configuration described in the first embodiment. For the insulating resin 50, an insulating material having higher thermal conductivity than a molding resin 13 is used. A dielectric strength voltage of the insulating resin 50 is preferably equal to or higher than that of the molding resin 13, but may be lower than that of the molding resin 13. Configurations of exposed surfaces of a source terminal 10, a gate terminal 11, and a drain terminal 12 on a package back surface SF2 are similar to those of the first embodiment described with reference to FIG. 2.

### 4.1.2 Cross-Sectional Configuration of Semiconductor Device

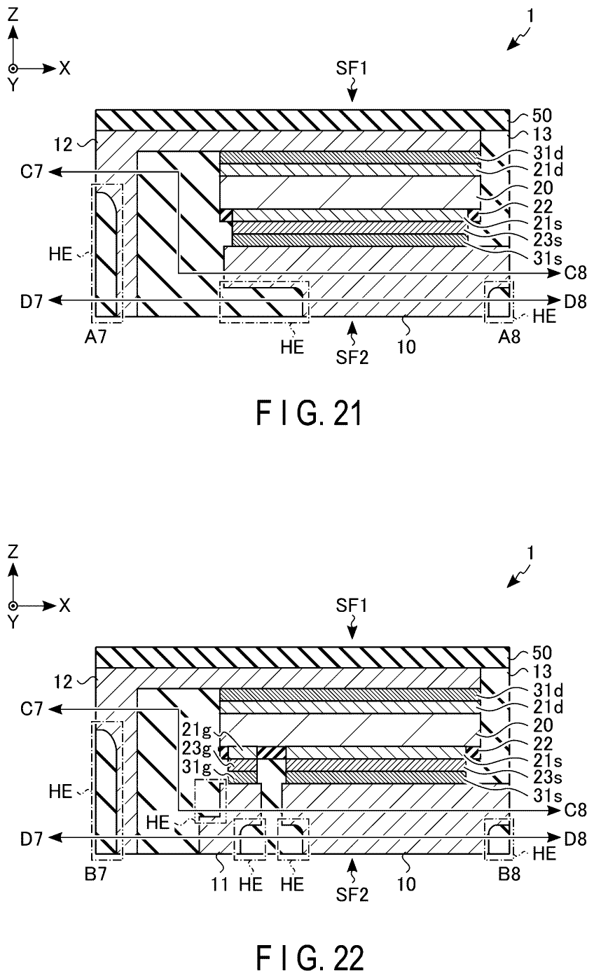

Next, an example of a cross-sectional configuration of the semiconductor device 1 will be described. FIG. 21 is a cross-sectional view taken along line A7-A8 of FIG. 20. FIG. 22 is a cross-sectional view taken along line B7-B8 in FIG. 20.

As illustrated in FIGS. 21 and 22, cross-sectional configurations of the source terminal 10, the gate terminal 11, and the drain terminal 12 are similar to those in the first embodiment described with reference to FIGS. 3 and 4.

For example, the insulating resin 50 is provided on an entire surface of the package front surface SF1 (the upper side in FIGS. 21 and 22). The insulating resin 50 is in contact with a surface of the drain terminal 12 facing the package front surface SF1. The molding resin 13 may be provided between the insulating resin 50 and the surface of the drain terminal 12 facing the package front surface SF1.

### 4.2 Method for Manufacturing Semiconductor Device

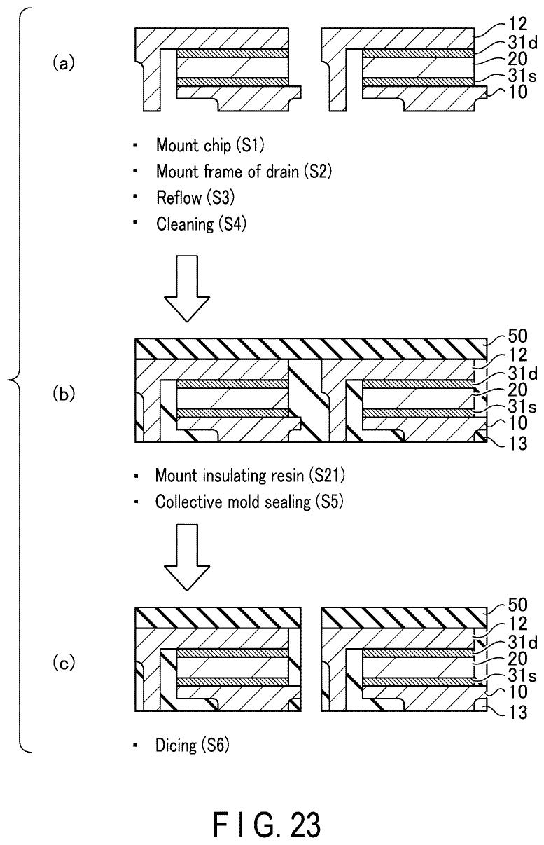

Next, an example of a method for manufacturing the semiconductor device 1 will be described. FIG. 23 is a diagram illustrating a flow of an assembly process. Note that the example of FIG. 23 illustrates a cross section of the semiconductor device 1 taken along line A7-A8 in FIG. 20, and the gate terminal 11 is omitted in order to simplify the description. Furthermore, in the example of FIG. 23, a source electrode 21s, a gate electrode 21g, a drain electrode 21d, a passivation film 22, and conductive layers 23s and 23g are omitted.

As illustrated in FIG. 23(a), first, a first etching frame provided with a plurality of source terminals 10 and a plurality of gate terminals 11 corresponding to a plurality of semiconductor devices 1 is prepared, as in the description in the first embodiment given with reference to FIG. 8. Each semiconductor chip 20 is mounted so that the source terminal 10 and the source electrode 21s are coupled with the mount material 31s interposed therebetween and the gate terminal 11 and the gate electrode 21g are coupled with the mount material 31g interposed therebetween (S1). Next, a second etching frame provided with the drain terminal 12 is mounted on the drain electrode 21d of the semiconductor chip 20 with a mount material 31d interposed therebetween (S2). The second etching frame is thicker than the first etching frame. In this state, reflow (S3) and cleaning (S4) are performed. Note that the mount material 31d, the semiconductor chip 20, the mount materials 31s and 31g, and the first etching frame provided with the source terminal 10 and the gate terminal 11 may be sequentially mounted on the second etching frame provided with the drain terminal 12.

As illustrated in FIG. 23(b), after the insulating resin 50 is formed (S21), the plurality of semiconductor devices 1 sharing the etching frames are collectively sealed with the molding resin 13 (S5). That is, a molding process is performed.

As illustrated in FIG. 23(c), the insulating resin 50, the molding resin 13, the first etching frame, and the second etching frame are cut by blade dicing (S6). The semiconductor devices 1 are thus cut into individual pieces. Cut surfaces of the first etching frame, the second etching frame, and the insulating resin 50 cut by the dicing may be exposed on a package side surface.

With the configuration according to the present embodiment, mounting capability of the semiconductor chip 20 can be improved as in the first embodiment.

Furthermore, with the configuration according to the present embodiment, in a case where the drain terminal 12 is not electrically connected to a wire on the package front surface SF1, the insulating resin 50 having higher thermal conductivity than the molding resin 13 can be provided on the package front surface SF1. This can improve heat dissipation of the semiconductor device 1.

The structure of the fourth embodiment can also be applied to the second embodiment.

### 5. Fifth Embodiment

Next, a fifth embodiment will be described. In the fifth embodiment, a power conversion apparatus 100 including a plurality of semiconductor devices 1 described in the first embodiment will be described. In the following description, a DC-DC converter will be described as an example of the power conversion apparatus 100. Differences from the first embodiment will be mainly described below. Note that any of the semiconductor devices 1 described in the second to fourth embodiments may be applied to the power conversion apparatus 100.

### 5.1 Circuit Configuration of Power Conversion Apparatus

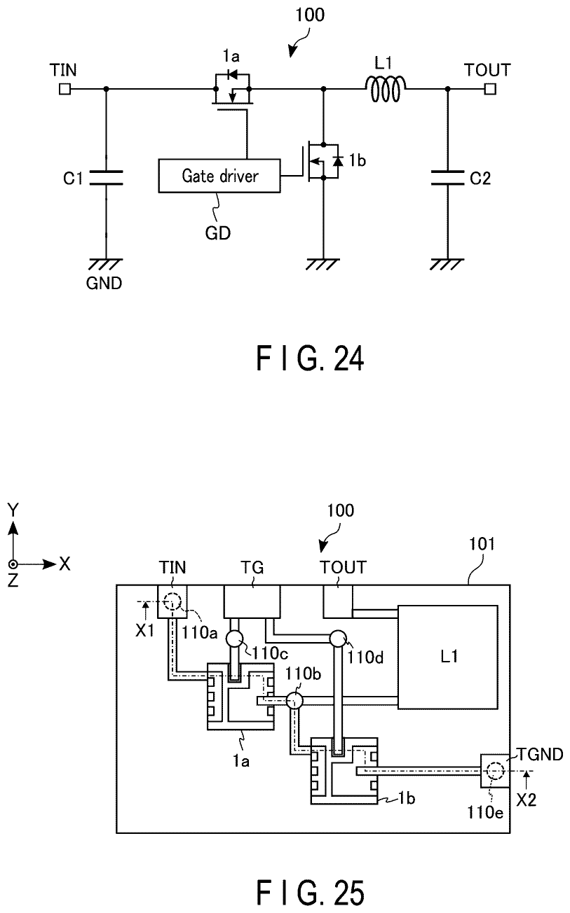

First, an example of a circuit configuration of the power conversion apparatus 100 will be described. FIG. 24 is a circuit diagram of the power conversion apparatus 100.

The power conversion apparatus 100 includes semiconductor devices 1a and 1b, an inductor L1, capacitors C1 and C2, and a gate driver GD. Each of the semiconductor devices 1a and 1b corresponds to the semiconductor device 1 of the first embodiment and includes a MOSFET. The power conversion apparatus 100 includes an input terminal TIN and an output terminal TOUT.

The input terminal TIN is coupled to a drain of the semiconductor device 1a. Furthermore, the input terminal TIN is coupled to a ground voltage node via the capacitor C1 (grounded to ground GND). For example, the ground voltage node is supplied with a ground voltage VSS.

A source of the semiconductor device 1a is coupled to a drain of the semiconductor device 1b and a first end of the inductor L1.

Gates of the semiconductor devices 1a and 1b are coupled to the gate driver GD.

A source of the semiconductor device 1b is coupled to a ground voltage node.

A second end of the inductor L1 is coupled to the output terminal TOUT. Furthermore, the second end of the inductor L1 is coupled to a ground voltage node via the capacitor C2.

### 5.2 Planar Configuration of Power Conversion Apparatus

Next, an example of a planar configuration of the power conversion apparatus 100 will be described. FIG. 25 is a plan view of the power conversion apparatus 100. The example of FIG. 25 is a plan view viewed from an upper surface side of a printed circuit board 101. In the following description, a surface on which the inductor L1 and others are surface-mounted and on which the input terminal TIN, the output terminal TOUT, and others are provided is referred to as a “printed circuit board upper surface”. A surface that is opposed to the mounting surface of the printed circuit board 101 is referred to as a “printed circuit board lower surface”. In the example of FIG. 25, the capacitors C1 and C2 are omitted in order to simplify the description.

As illustrated in FIG. 25, the power conversion apparatus 100 includes the semiconductor devices 1a and 1b, the printed circuit board 101, the gate driver GD, the inductor L1, and the capacitors C1 and C2. The semiconductor device 1a and the semiconductor device 1b are arranged such that package back surfaces SF2 face a printed circuit board upper surface side. In other words, package front surfaces SF1 of the semiconductor device 1a and the semiconductor device 1b face a printed circuit board lower surface side. Hereinafter, such an arrangement is referred to as “drain down”.

Drain terminals 12 of the semiconductor device 1a and the semiconductor device 1b are coupled to a wiring layer of the printed circuit board 101 on the respective package front surfaces SF1.

### 5.3 Cross-Sectional Configuration of Power Conversion Apparatus

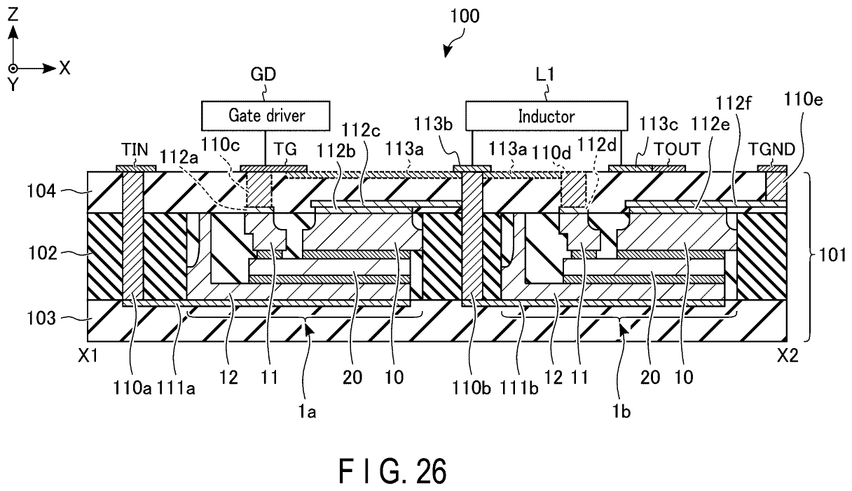

Next, an example of a cross-sectional configuration of the power conversion apparatus 100 will be described. FIG. 26 is a cross-sectional view of the power conversion apparatus 100 taken along line X1-X2 in FIG. 25. In the example of FIG. 26, not only a cross section but also portions of members such as a contact plug and a wiring layer that can be seen through the cross section are indicated by broken lines. In the example of FIG. 26, the capacitors C1 and C2 are omitted in order to simplify the description.

As illustrated in FIG. 26, the power conversion apparatus 100 has a structure in which the semiconductor devices 1a and 1b are embedded in the printed circuit board 101 in a drain-down manner. For example, the gate driver GD and the inductor L1 are surface-mounted on the printed circuit board upper surface of the printed circuit board 101.

The printed circuit board 101 is a multilayer wiring board including a plurality of wiring layers, a plurality of insulating plates (or insulating layers), and a core material. More specifically, the printed circuit board 101 includes a core material (or an insulating material) 102, insulating plates (or insulating layers) 103 and 104, contact plugs 110a, 110b, 110c, 110d, and 110e, wiring layers 111a, 111b, 112a, 112b, 112c, 112d, 112f, 113a, 113b, and 113c, the input terminal TIN, the output terminal TOUT, a gate driver terminal TG, and a ground terminal TGND (that is, a ground voltage node).

Each of insulating plates 103 and 104 has, for example, a sheet shape and is made of an insulating material in which carbon fibers are impregnated with a thermosetting resin. The contact plugs 110a, 110b, 110c, 110d, and 110e and the wiring layers 111a, 111b, 112a, 112b, 112c, 112d, 112f, 113a, 113b, and 113c are made of a conductive material, and contain, for example, copper.

The semiconductor devices 1a and 1b are embedded in the printed circuit board 101. More specifically, the semiconductor devices 1a and 1b are provided between the insulating plate 103 and the insulating plate 104 in the Z direction. The semiconductor devices 1a and 1b are provided between the core materials 102 in the X direction and the Y direction. The semiconductor devices 1a and 1b are disposed such that the package front surfaces SF1 thereof face the insulating plate 103. Exposed surfaces of a source terminal 10 and a gate terminal 11 of the semiconductor devices 1a and 1b face the insulating plate 104 (the printed circuit board upper surface).

In other words, the semiconductor devices 1a and 1b in the drain-down state are provided away from each other on the insulating plate 103. The insulating plate 104 is provided on the semiconductor devices 1a and 1b (package back surface side). Side surfaces of the semiconductor devices 1a and 1b are in contact with the core material 102. That is, the semiconductor devices 1a and 1b are provided in the same layer as the core material 102.

The input terminal TIN, the output terminal TOUT, the gate driver terminal TG, and the ground terminal TGND are provided on the insulating plate 104.

The contact plugs 110a and 110b are provided in the insulating plate 104 and the core material 102. Each of the contact plugs 110a and 110b extends in the Z direction in the insulating plate 104 and the core material 102.

The contact plugs 110c, 110d, and 110e are provided in the insulating plate 104. The contact plugs 110c, 110d, and 110e extend in the Z direction in the insulating plate 104.

The wiring layer 111a is provided between the drain terminal 12 of the semiconductor device 1a and the insulating plate 103. The wiring layer 111a extends on the XY plane. The wiring layer 112a is provided between the gate terminal 11 of the semiconductor device 1a and the insulating plate 104. The wiring layer 112a extends on the XY plane. The wiring layers 112b and 112c are provided between the source terminal 10 of the semiconductor device 1a and the insulating plate 104. The wiring layers 112b and 112c extend on the XY plane.

The wiring layer 111b is provided between the drain terminal 12 of the semiconductor device 1b and the insulating plate 103. The wiring layer 111b extends on the XY plane. The wiring layer 112d is provided between the gate terminal 11 of the semiconductor device 1b and the insulating plate 104. The wiring layers 112e and 112f are provided between the source terminal 10 of the semiconductor device 1b and the insulating plate 104. The wiring layers 112e and 112f extend on the XY plane.

The wiring layers 113a, 113b, and 113c are provided on the insulating plate 104. The wiring layers 113a, 113b, and 113c extend on the XY plane.

The input terminal TIN is coupled to the contact plug 110a. The contact plug 110a is coupled to the wiring layer 111a. The wiring layer 111a is coupled to the drain terminal 12 of the semiconductor device 1a on the package front surface SF1 of the semiconductor device 1a (lower side in FIG. 26).

The gate terminal 11 of the semiconductor device 1a is coupled to the contact plug 110c via the wiring layer 112a. The contact plug 110c is coupled to the gate driver terminal TG.

The source terminal 10 of the semiconductor device 1a is coupled to the contact plug 110b via the wiring layers 112b and 112c.

The contact plug 110b is coupled to the wiring layer 111b and the wiring layer 113b. The wiring layer 111b is coupled to the drain terminal 12 of the semiconductor device 1b on the package front surface SF1 of the semiconductor device 1b (lower side in FIG. 26). The wiring layer 113b is coupled to the first end of the inductor L1. The second end of the inductor L1 is coupled to the output terminal TOUT via the wiring layer 113c. The inductor L1 is, for example, surface-mounted on the printed circuit board 101.

The gate terminal 11 of the semiconductor device 1b is coupled to the contact plug 110d via the wiring layer 112d. The contact plug 110d is coupled to the gate driver terminal TG via the wiring layer 113a. The gate driver terminal TG is coupled to the gate driver GD.

The source terminal 10 of the semiconductor device 1b is coupled to the contact plug 110e via the wiring layers 112e and 112f. The contact plug 110e is coupled to the ground terminal TGND.

With the configuration according to the present embodiment, the semiconductor devices 1a and 1b can be easily mounted so as to be embedded in the printed circuit board 101, and the power conversion apparatus 100, for example, a DC-DC converter can be formed to have a small area. Other effects are similar to those of the first embodiment.

### 6. Sixth Embodiment

Next, a sixth embodiment will be described. In the sixth embodiment, a configuration of a power conversion apparatus 100 different from that of the fifth embodiment will be described. Differences from the fifth embodiment will be mainly described below.

### 6.1 Planar Configuration of Power Conversion Apparatus

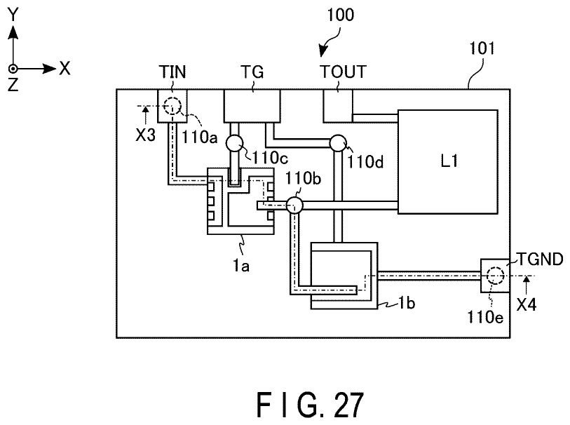

First, an example of a planar configuration of the power conversion apparatus 100 will be described. FIG. 27 is a plan view of the power conversion apparatus 100. The example of FIG. 27 is a plan view viewed from an upper surface side of a printed circuit board 101. In the example of FIG. 27, capacitors C1 and C2 are omitted in order to simplify the description.

As illustrated in FIG. 27, the power conversion apparatus 100 includes semiconductor devices 1a and 1b, the printed circuit board 101, a gate driver GD, an inductor L1, and the capacitors C1 and C2. The semiconductor device 1a is disposed in a drain-down manner. The semiconductor device 1b is arranged such that a package front surface SF1 faces a printed circuit board upper surface side. In other words, a package back surface SF2 of the semiconductor device 1b faces a printed circuit board lower surface side. That is, exposed surfaces of a source terminal 10 and a gate terminal 11 face the printed circuit board lower surface side. Hereinafter, such an arrangement is referred to as “source down”.

Drain terminals 12 of the semiconductor device 1a and the semiconductor device 1b are coupled to a wiring layer of the printed circuit board 101 on the respective package front surfaces SF1.

### 6.2 Cross-Sectional Configuration of Power Conversion Apparatus

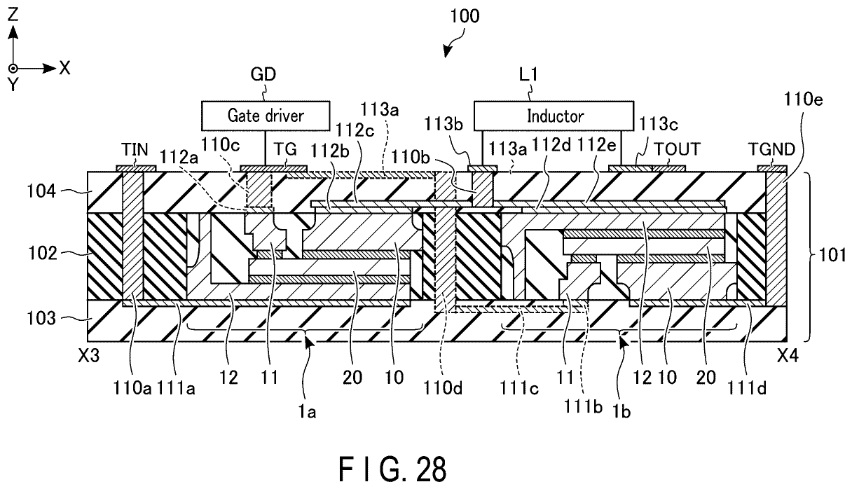

Next, an example of a cross-sectional configuration of the power conversion apparatus 100 will be described. FIG. 28 is a cross-sectional view of the power conversion apparatus 100 taken along line X3-X4 in FIG. 27. In the example of FIG. 28, not only a cross section but also portions of members such as a contact plug and a wiring layer that can be seen through the cross section are indicated by broken lines. In the example of FIG. 28, the capacitors C1 and C2 are omitted in order to simplify the description.

As illustrated in FIG. 28, the printed circuit board 101 includes a core material 102, insulating plates 103 and 104, contact plugs 110a, 110b, 110c, 110d, and 110e, wiring layers 111a, 111b, 111c, 111d, 112a, 112b, 112c, 112d, 112e, 113a, 113b, and 113c, an input terminal TIN, an output terminal TOUT, a gate driver terminal TG, and a ground terminal TGND.

The semiconductor devices 1a and 1b are embedded in the printed circuit board 101. In the present embodiment, the semiconductor device 1a is disposed such that the package front surface SF1 faces the insulating plate 103. The semiconductor device 1b is disposed such that the package back surface SF2 faces the insulating plate 103. Exposed surfaces of the source terminal 10 and the gate terminal 11 of the semiconductor device 1a face the insulating plate 104 (the printed circuit board upper surface). Exposed surfaces of the source terminal 10 and the gate terminal 11 of the semiconductor device 1b face the insulating plate 103 (the printed circuit board lower surface).

In other words, the semiconductor device 1a in the drain-down state and the semiconductor device 1b in the source-down state are provided away from each other on the insulating plate 103. The insulating plate 104 is provided on the semiconductor devices 1a and 1b. Side surfaces of the semiconductor devices 1a and 1b are in contact with the core material 102. That is, the semiconductor devices 1a and 1b are provided in the same layer as the core material 102.

The input terminal TIN, the output terminal TOUT, the gate driver terminal TG, and the ground terminal TGND are provided on the insulating plate 104.

The contact plugs 110a, 110d, and 110e are provided in the insulating plate 104 and the core material 102. Each of the contact plugs 110a, 110d, and 110e extends in the Z direction in the insulating plate 104 and the core material 102.

The contact plugs 110b and 110c are provided in the insulating plate 104. The contact plugs 110b and 110c extend in the Z direction in the insulating plate 104.

The wiring layer 111a is provided between the drain terminal 12 of the semiconductor device 1a and the insulating plate 103. The wiring layer 111a extends on the XY plane. The wiring layer 112a is provided between the gate terminal 11 of the semiconductor device 1a and the insulating plate 104. The wiring layer 112a extends on the XY plane. The wiring layers 112b and 112c are provided between the source terminal 10 of the semiconductor device 1a and the insulating plate 104. The wiring layers 112b and 112c extend on the XY plane.

The wiring layers 111b and 111c are provided between the gate terminal 11 of the semiconductor device 1b and the insulating plate 103. The wiring layers 111b and 111c extend on the XY plane. The wiring layer 111d is provided between the source terminal 10 of the semiconductor device 1b and the insulating plate 103. The wiring layers 112d and 112e are provided between the drain terminal 12 of the semiconductor device 1b and the insulating plate 104. The wiring layers 112d and 112e extend on the XY plane.

The wiring layers 113a, 113b, and 113c are provided on the insulating plate 104. The wiring layers 113a, 113b, and 113c extend on the XY plane.

The input terminal TIN is coupled to the contact plug 110a. The contact plug 110a is coupled to the wiring layer 111a. The wiring layer 111a is coupled to the drain terminal 12 of the semiconductor device 1a on the package front surface SF1 of the semiconductor device 1a (lower side in FIG. 28).

The gate terminal 11 of the semiconductor device 1a is coupled to the contact plug 110c via the wiring layer 112a. The contact plug 110c is coupled to the gate driver terminal TG.

The gate driver terminal TG is coupled to the contact plug 110d via the wiring layer 113a. The contact plug 110d is coupled to the gate terminal 11 of the semiconductor device 1b via the wiring layer 111c and the wiring layer 111b.

The source terminal 10 of the semiconductor device 1a is coupled to the contact plug 110b via the wiring layers 112b and 112c.

The contact plug 110b is coupled to the wiring layer 112e and the wiring layer 113b. The wiring layer 112e is coupled to the wiring layer 112d. The wiring layer 112d is coupled to the drain terminal 12 of the semiconductor device 1b on the package front surface SF1 of the semiconductor device 1b (upper side in FIG. 28). The wiring layer 113b is coupled to the first end of the inductor L1. The second end of the inductor L1 is coupled to the output terminal TOUT via the wiring layer 113c.

The source terminal 10 of the semiconductor device 1b is coupled to the contact plug 110e via the wiring layer 111d. The contact plug 110e is coupled to the ground terminal TGND.

With the configuration according to the present embodiment, similar effects to those of the fifth embodiment can be obtained. Other effects are similar to those of the first embodiment.

### 7. Seventh Embodiment

Next, a seventh embodiment will be described. In the seventh embodiment, a configuration of a power conversion apparatus 100 different from that of the fifth and sixth embodiments will be described. Differences from the fifth and sixth embodiments will be mainly described below.

### 7.1 Planar Configuration of Power Conversion Apparatus

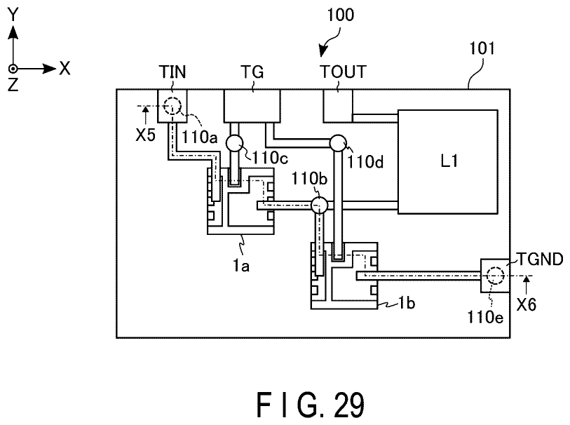

First, an example of a planar configuration of the power conversion apparatus 100 will be described. FIG. 29 is a plan view of the power conversion apparatus 100. The example of FIG. 29 is a plan view viewed from an upper surface side of a printed circuit board 101. In the example of FIG. 29, capacitors C1 and C2 are omitted in order to simplify the description.

As illustrated in FIG. 29, the power conversion apparatus 100 includes semiconductor devices 1a and 1b, the printed circuit board 101, a gate driver GD, an inductor L1, and the capacitors C1 and C2. The semiconductor devices 1a and 1b are disposed in a drain-down manner, as in the fifth embodiment.

In the present embodiment, drain terminals 12 of the semiconductor device 1a and the semiconductor device 1b are coupled to a wiring layer of the printed circuit board 101 on respective package back surfaces SF2.

### 7.2 Cross-Sectional Configuration of Power Conversion Apparatus

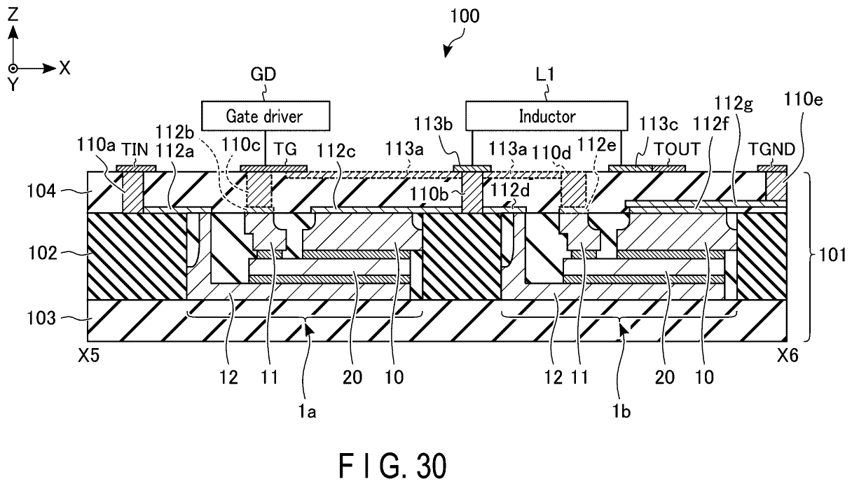

Next, an example of a cross-sectional configuration of the power conversion apparatus 100 will be described. FIG. 30 is a cross-sectional view of the power conversion apparatus 100 taken along line X5-X6 in FIG. 29. In the example of FIG. 30, not only a cross section but also portions of members such as a contact plug and a wiring layer that can be seen through the cross section are indicated by broken lines. In the example of FIG. 30, the capacitors C1 and C2 are omitted in order to simplify the description.

As illustrated in FIG. 30, the printed circuit board 101 includes a core material 102, insulating plates 103 and 104, contact plugs 110a, 110b, 110c, 110d, and 110e, wiring layers 112a, 112b, 112c, 112d, 112e, 112f, 112g, 113a, 113b, and 113c, an input terminal TIN, an output terminal TOUT, a gate driver terminal TG, and a ground terminal TGND.

The semiconductor devices 1a and 1b are embedded in the printed circuit board 101. In the present embodiment, the semiconductor devices 1a and 1b are arranged in a drain-down manner, as in the fifth embodiment.

In other words, the semiconductor devices 1a and 1b in the drain-down state are provided away from each other on the insulating plate 103. The insulating plate 104 is provided on the semiconductor devices 1a and 1b. Side surfaces of the semiconductor devices 1a and 1b are in contact with the core material 102. That is, the semiconductor devices 1a and 1b are provided in the same layer as the core material 102.

The input terminal TIN, the output terminal TOUT, the gate driver terminal TG, and the ground terminal TGND are provided on the insulating plate 104.

The contact plugs 110a, 110b, 110c, 110d, and 110e are provided in the insulating plate 104. The contact plugs 110a, 110b, 110c, 110d, and 110e extend in the Z direction in the insulating plate 104.

The wiring layer 112a is provided between the drain terminal 12 of the semiconductor device 1a and the insulating plate 104. The wiring layer 112a extends on the XY plane. The wiring layer 112b is provided between the gate terminal 11 of the semiconductor device 1a and the insulating plate 104. The wiring layer 112b extends on the XY plane. The wiring layer 112c is provided between the source terminal 10 of the semiconductor device 1a and the insulating plate 104. The wiring layer 112c extends on the XY plane.

The wiring layer 112d is provided between the drain terminal 12 of the semiconductor device 1b and the insulating plate 104. The wiring layer 112d extends on the XY plane. The wiring layer 112e is provided between the gate terminal 11 of the semiconductor device 1b and the insulating plate 104. The wiring layer 112e extends on the XY plane. The wiring layers 112f and 112g are provided between the source terminal 10 of the semiconductor device 1b and the insulating plate 104. The wiring layers 112f and 112g extend on the XY plane.

The wiring layers 113a, 113b, and 113c are provided on the insulating plate 104. The wiring layers 113a, 113b, and 113c extend on the XY plane.

The input terminal TIN is coupled to the contact plug 110a. The contact plug 110a is coupled to the wiring layer 112a. The wiring layer 112a is coupled to the drain terminal 12 of the semiconductor device 1a on the package back surface SF2 of the semiconductor device 1a (upper side in FIG. 30).

The gate terminal 11 of the semiconductor device 1a is coupled to the contact plug 110c via the wiring layer 112b. The contact plug 110c is coupled to the gate driver terminal TG.

The gate driver terminal TG is coupled to the contact plug 110d via the wiring layer 113a. The contact plug 110d is coupled to the gate terminal 11 of the semiconductor device 1b via the wiring layer 112e.

The source terminal 10 of the semiconductor device 1a is coupled to the contact plug 110b via the wiring layer 112c.

The contact plug 110b is coupled to the wiring layer 112d and the wiring layer 113b. The wiring layer 112d is coupled to the drain terminal 12 of the semiconductor device 1b on the package back surface SF2 of the semiconductor device 1b (upper side in FIG. 30). The wiring layer 113b is coupled to the first end of the inductor L1. The second end of the inductor L1 is coupled to the output terminal TOUT via the wiring layer 113c.

The source terminal 10 of the semiconductor device 1b is coupled to the contact plug 110e via the wiring layers 112f and 112g. The contact plug 110e is coupled to the ground terminal TGND.

With the configuration according to the present embodiment, similar effects to those of the fifth embodiment can be obtained. Other effects are similar to those of the first embodiment.

### 8. Modifications and Others

Although the case where the semiconductor devices 1a and 1b are embedded in the printed circuit board 101 has been described in the fifth to seventh embodiments, the configuration of the power conversion apparatus 100 is not limited. For example, at least one of the semiconductor devices 1a and 1b may be surface-mounted on the printed circuit board 101.

The semiconductor devices 1a and 1b may be embedded in the printed circuit board 101 in a source-down manner.

The semiconductor device 1 of the second embodiment may be applied to the fifth to seventh embodiments.

The semiconductor device 1 of the third or fourth embodiment may be applied to the seventh embodiment.

The “coupling” in the above embodiments also includes a state where elements are indirectly coupled with another conductive material interposed therebetween.

The “substantially the same” in the above embodiments may include manufacturing variations.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor chip having a first surface on which a source electrode and a gate electrode are provided and a second surface that is opposed to the first surface and on which a drain electrode is provided;
a source terminal having a fourth surface exposed from a third surface of a package and a fifth surface coupled to the source electrode and having a shape different from a shape of the fourth surface;
a gate terminal having a sixth surface exposed from the third surface of the package and a seventh surface coupled to the gate electrode and having a shape different from a shape of the sixth surface; and
a drain terminal coupled to the drain electrode and having an eighth surface exposed from the third surface of the package.

2. The semiconductor device according to claim 1, wherein
in a case where the semiconductor device is surface-mounted on a printed circuit board, the fourth surface, the sixth surface, and the eighth surface are covered with tin or solder, and
in a case where the semiconductor device is mounted vertically on a printed circuit board, the fourth surface, the sixth surface, and the eighth surface are not covered with tin and solder.

3. The semiconductor device according to claim 1, wherein
each of the source terminal, the gate terminal, and the drain terminal is formed from an etching frame.

4. The semiconductor device according to claim 1, wherein
each of the source terminal, the gate terminal, and the drain terminal has a first region half-etched in a first direction from the third surface side of the package, and
the gate terminal further has a second region half-etched from the seventh surface side.

5. The semiconductor device according to claim 4, wherein
a length in the first direction of the first region of the drain terminal is longer than a length in the first direction of the first region of each of the source terminal and the gate terminal.

6. The semiconductor device according to claim 4, wherein
a length in the first direction of the first region of the source terminal is identical to a length in the first direction of the first region of the gate terminal.

7. The semiconductor device according to claim 1, wherein
a length in a first direction of the drain terminal is longer than a length in the first direction of each of the source terminal and the gate terminal.

8. The semiconductor device according to claim 1, wherein
the drain terminal includes a first portion coupled to the drain electrode with a mount material interposed therebetween, and a second portion having one end coupled to the first portion, extending in a first direction, and having another end having the eighth surface exposed from the third surface of the package.

9. The semiconductor device according to claim 7, wherein
the length in the first direction of the drain terminal is identical to a length in the first direction of the package.

10. The semiconductor device according to claim 8, wherein
the first portion of the drain terminal has a tenth surface exposed from a ninth surface opposed to the third surface of the package.

11. The semiconductor device according to claim 8, wherein
the drain terminal further includes a third portion having one end coupled to the first portion, extending in the first direction, facing the second portion with the semiconductor chip interposed therebetween, and having another end having an eleventh surface exposed from the third surface of the package.

12. The semiconductor device according to claim 1, further comprising
a conductive heat sink exposed from a ninth surface opposed to the third surface of the package and insulated from the source terminal, the gate terminal, and the drain terminal.

13. The semiconductor device according to claim 1, further comprising
an insulating resin that is exposed from a ninth surface opposed to the third surface of the package, is in contact with the drain terminal, and has a higher thermal conductivity than a molding resin.

14. A method for manufacturing a semiconductor device in which a source terminal, a gate terminal, and a drain terminal are exposed from a first surface of a package, the method comprising:
mounting a semiconductor chip on the source terminal and the gate terminal provided in a first etching frame such that a source electrode is coupled to the source terminal with a mount material interposed therebetween and a gate electrode is coupled to the gate terminal with the mount material interposed therebetween;
mounting the drain terminal provided in a second etching frame having a thickness different from a thickness of the first etching frame on a drain electrode with the mount material interposed therebetween, the drain electrode being provided on a surface of the semiconductor chip opposed to a surface on which the source electrode and the gate electrode are provided;
sealing the first etching frame, the semiconductor chip, and the second etching frame with a molding resin; and
cutting the first etching frame, the second etching frame, and the molding resin.

15. The method for manufacturing a semiconductor device according to claim 14, wherein
each of the source terminal, the gate terminal, and the drain terminal has a first region half-etched in a first direction from the first surface side of the package.

16. The method for manufacturing a semiconductor device according to claim 14, wherein
the drain terminal is further exposed from a second surface opposed to the first surface of the package.

17. The method for manufacturing a semiconductor device according to claim 14, wherein
a length in a first direction of the drain terminal is identical to a length in the first direction of the package.

18. The method for manufacturing a semiconductor device according to claim 14, further comprising
mounting a conductive heat sink exposed from a second surface opposed to the first surface of the package and insulated from the source terminal, the gate terminal, and the drain terminal.

19. The method for manufacturing a semiconductor device according to claim 14, further comprising
forming an insulating resin that is exposed from a second surface opposed to the first surface of the package, is in contact with the drain terminal, and has a higher thermal conductivity than the molding resin.

20. A power conversion apparatus comprising:
a first insulating plate;
a second insulating plate facing the first insulating plate;
the semiconductor device according to claim 1 provided between the first insulating plate and the second insulating plate; and
a core material provided in a same layer as the semiconductor device.
